(19) United States
(12) Patent Application Publication
(10) Pub. No.: US 2025/0133686 A1
(43) Pub. Date: Apr. 24, 2025

(54) RACK ARCHITECTURE

(71) Applicant: Natron Energy, Inc., Santa Clara, CA (US)

(72) Inventors: Gopalakrishnan Parakulam, Dublin, CA (US); Stevan Polak, Los Gatos, CA (US); Ruoyu Zhang, Newark, CA (US)

(73) Assignee: Natron Energy, Inc., Santa Clara, CA (US)

(21) Appl. No.: 18/671,012

(22) Filed: May 22, 2024

Related U.S. Application Data
(63) Continuation of application No. 63/468,236, filed on May 22, 2023.

(51) Int. Cl. H05K 7/18; H05K 7/14

(52) U.S. Cl. CPC H05K 7/183; H05K 7/1492

(57) ABSTRACT

A system and method for providing a short-term power bridging architecture, particularly tailored to improvements in electrochemical cell packs that include an aggregation of electrochemical cells having at least one electrode using a TMCCC. A rack architecture for a power bridging rack, includes a power path; and a low voltage path; wherein elements disposed in the power path include protection elements and provide a protection function; wherein the low voltage path is divided into a control section and an interface section; wherein the control section provides a balance function; and wherein the interface section interfaces to one or more devices.

### CROSS REFERENCE TO RELATED APPLICATIONS

This Application claims the benefit of U.S. Provisional Application 63/468,236 filed on May 22, 2023; this Application is related to U.S. Provisional Application 63/468,243 filed on May 22, 2023 and is related to U.S. application Ser. No. 18/671,438 filed on the same day and claiming benefit of U.S. Application 63/468,243), the contents of all these applications are hereby expressly incorporated by reference thereto in their entireties for all purposes.

### FIELD OF THE INVENTION

The present invention relates generally to power delivery and power delivery management systems and methods, particularly power delivery systems including electrochemical cells including a coordination compound electrochemically active in one or more electrodes, and more specifically, but not exclusively, to improvement in architectures, controls, and implementations of power bridging solutions.

### BACKGROUND OF THE INVENTION

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches, which in and of themselves may also be inventions.

Applicant has developed improved electrochemical cells using transition metal cyanide coordination compounds (TMCCCs) in one or more electrode structures. These materials offer improved performance characteristics that may be incorporated into new and improved power and energy solutions. This application pertains primarily to improvements in power cell solutions, such as power bridging among other applications.

For some time, there has been an increasing demand for backup power, this demand has become a major issue for both consumers and electricians because voltage surges can bring an entire home or office to a standstill. There are often opportunities to bridge a downtime during a switching transition by supporting a critical energy load during a failing, transitioning, and/or starting power source, such as moving to a stable alternate source as quickly as possible. There are a range of bridging products in the marketplace, differentiated in part by the type of electrochemical cell/structure such as those that use lead-acid batteries, low-and high-speed flywheels and ultra capacitors, among others.

Lead-acid batteries are the cheapest and most popular option, but they have a shorter life-span than other alternatives for short-term storage. These batteries must be kept at 25 degrees Celsius because higher temperatures shorten their life and lower temperatures reduce the capacity. Lead-acid batteries should be stored in temperature-controlled environments to preserve the life of the battery.

Flywheels have a longer cycle life because power is provided from a primary source via an open transfer switch. Flywheels are charged and then discharged, using a generator. These units have enough stored power to encounter voltage sags and momentary service interruptions. Computer and manufacturing facilities may use flywheels to enable backup generators to be up and running within five to 10 seconds.

Ultra-capacitors, which can also be charged more quickly than batteries, are most popular for very short-term applications where voltage sags last only a few seconds. Although their initial cost may be about 10 times more than lead-acid batteries, their advantage is much greater, having a cycle life that is much better than lead-acid batteries, yielding about five times the power capability and longer life. Ultra-capacitors have a high tolerance for temperature and are more efficient during the charge/discharge cycle. A disadvantage of the ultra-capacitor is cost, but for short-term applications, they are cost competitive due to their higher power density.

There are uninterrupted power solutions (UPS) that may sometimes be used in some situations. This off-line or standby technology can be a cost-effective approach for small stand-alone applications like PCs and peripherals. With this type of unit, power comes directly from power mains (e.g., A/C outlet) until the voltage fails. When this happens, a battery-powered inverter turns on to continue the power supply while the UPS provides protection from surges.

Similar to a standby system, line-interactive technology provides power conditioning that can be effective to provide a UPS backup. But, unlike an off-line unit, line-interactive power condition may provide an automatic voltage boost when the power goes down, without accessing the batteries. In areas where power outages are infrequent, but there are often power fluctuations, such a system may be advantageous.

An on-line alternative may provide a very high level of power protection, conditioning and UPS available. Using double conversion technology, a UPS changes an incoming alternate current to direct current, then conditions it to eliminate noise or surges, and converts it to AC before it exits the UPS. Since the power runs continuously through the inverter, there is no transfer or switching time to battery mode in the event of a blackout.

UPSs may provide a “clean” source of power, eliminating noise that can cause interruptions in operations or data loss. They provide batteries for backup power to a system in the event of a power outage to enable time to safely save all open files and to shut down the system until normal power can be restored. Several hours of work can be lost due to a momentary brownout where the AC power supply slumps to a level under 100 volts, which can crash a computer before the work can be saved to a disk. Generally speaking, power surges often accompany brownouts as the power rebounds to normal. Brownouts often pass unnoticed when a UPS is used as part of a necessary power protection system.

Improvements in technologies coming to bridge the gap for standby power are desired. Older technologies included having a backup system with 15 to 30 minutes of battery time. Some solutions require some period, e.g., 15 or 30 seconds to start a backup/bridging generator, but there is a time in between where there is a gap. Most businesses are not operable without computers or other power consuming devices/equipment, and today they realize the need for power continuity across many use cases.

Fuel-free backup power systems are available and can be installed indoors, require low maintenance and produce no noise, smoke or emissions. A question for almost all businesses: when power terminates, planned or unexpected, would the business be able to continue to operate systems without interruption, particularly those that are critical to needs? Every hospital has a generator that will turn on when the electricity goes off, but they also require a backup power solution to bridge the 15- to 30-second gap needed to start the generator For those on life-support systems, this is obviously a critical situation. Business operations will not stop because of a power failure and valuable data is not lost.

With the increased use of local area networks, offices are becoming more and more susceptible to power issues. Because most files are stored on networks on one high-speed file server, a simple brownout could affect several users at a time. The recent increase in digital phone system use makes them vulnerable to power problems, as many businesses are now conducting all their business over the phone.

Even though no facility has perfect power quality, the electric company tries to supply homes and offices with a steady source of maximum current electricity. When the supply does not contain a stable voltage, frequency and source of maximum current, there is a power quality problem. Many people once believed that poor power quality has no cost as long as there are no obvious manifestations like breakers being tripped, equipment being burned or issues in production operations.

Poor power quality does affect electronic and motor loads, which can become damaged and create the largest cost to repair. Voltage and frequency variations can cause problems with both loads. A weak current limits these power loads, overheats an operation and leads to premature failure. Motors are the biggest victims of poor power quality. Once a motor fails, it is generally repaired or replaced but more often than not, the cause of the failure is not diagnosed. Because of poor power quality, the lifetime of a motor can be significantly reduced, for example lifetime cut in half.

Electric utilities have been monitoring their power lines for decades in an effort to prevent electrical disturbances. The result ensures compatibility between equipment and the electrical environment. Generators are generally not a complete solution to power interruptions. Some concerns mentioned above is that it takes time to start them and bring them online. There is a need to bridge that gap. Problems with traditional power bridging include systems that people believe are too expensive; they may replacing batteries or implement no or insufficient solutions.

Only incandescent light bulbs and resistive heating elements demand perfect power while most other loads impose their own demands on the available electrical supply. Because of this, the demand of all inductive loads is for an unusual type of current. Resistive loads demand their current at the same time in each cycle, as the voltage is available.

Bridging power applications, stabilizing voltage and providing regulation for short-term energy solutions requires high-quality electric power. These systems with power bridging components use a fast-acting storage system to bridge the gap when slower starting, long-term systems are unable to do so. Short-term bridging power product availability may be improved and storage technologies that can provide immediate response with longer life are needed.

What may be beneficial is a system and method for providing a short-term power bridging architecture, particularly tailored to improvements in electrochemical cell packs that include an aggregation of electrochemical cells having at least one electrode using a TMCCC.

### BRIEF SUMMARY OF THE INVENTION

Disclosed is a system and method for providing a short-term power bridging architecture, particularly tailored to improvements in electrochemical cell packs that include an aggregation of electrochemical cells having at least one electrode using a TMCCC. The following summary of the invention is provided to facilitate an understanding of some of the technical features related to a new architecture for power bridging, and is not intended to be a full description of the present invention. A full appreciation of the various aspects of the invention can be gained by taking the entire specification, claims, drawings, and abstract as a whole. The present invention is applicable to other electrochemical cells having high power density in addition to TMCCC materials.

An embodiment may further include additional monitoring of the power rail, such as for safety monitoring to meet particular application requirements—however the control features remains the same.

An embodiment may further include an improvement in paralleling—for example an ability of embodiments to parallel multiple (e.g., two) racks easily with an appropriate interface boards.

An embodiment of the present invention may include an improved precharge capability—in an event that a pack falls very close to zero volts (within a predetermined threshold such as a below an Undervoltage threshold that may be set by a user or system), some embodiments of the present invention may be easily recovered through a disclosed precharge capability.

An embodiment of the present invention may include a black start capability—for example an ability of a system to bootstrap from its power to start up without any need or use of an external Vbus voltage to start the system.

An embodiment of the present invention may include a decoupling of a user from core functionality—a user interface board is provided that processes user interface functions with that processing decoupled from system functionality. In an example, an embodiment of a rack system may function without such a user interface board. The user interface board may provide enhanced features, such as for example, connecting two racks in parallel.

A bridging power architecture that supports a three-wire power transmission system that includes both voltage sensing and current sensing for both +Ve and −Ve paths.

A bridging power architecture that provides a greater facility to scale a number of power packs≥for example, a number of packs that may be connected in series may be easily scaled from 1 to N, for example N≥2, such as N=8, 10, or 16. One reason for this facility is a separation of a control and power rail components: the control logic is not required to scale while the power rail components may be configured for increased possible maximum power. For example, a split bus option does not impact the control rail aspect.

An embodiment of the present invention for a rack architecture may include one or more of the following: (a) a rack architecture divided into a power path and a low voltage path. Elements disposed in the power path are sometimes referred to as protection elements and provide protection function; (b) rack architecture low voltage path is divided into a control section and an interface section wherein the control section provides a balance function and the interface section interfaces to devices outside the pack.

Any of the embodiments described herein may be used alone or together with one another in any combination. Inventions encompassed within this specification may also include embodiments that are only partially mentioned or alluded to or are not mentioned or alluded to at all in this brief summary or in the abstract. Although various embodiments of the invention may have been motivated by various deficiencies with the prior art, which may be discussed or alluded to in one or more places in the specification, the embodiments of the invention do not necessarily address any of these deficiencies. In other words, different embodiments of the invention may address different deficiencies that may be discussed in the specification. Some embodiments may only partially address some deficiencies or just one deficiency that may be discussed in the specification, and some embodiments may not address any of these deficiencies.

Other features, benefits, and advantages of the present invention will be apparent upon a review of the present disclosure, including the specification, drawings, and claims.

### BRIEF DESCRIPTION OF THE DRAWINGS

The accompanying figures, in which like reference numerals refer to identical or functionally-similar elements throughout the separate views and which are incorporated in and form a part of the specification, further illustrate the present invention and, together with the detailed description of the invention, serve to explain the principles of the present invention.

FIG. 1 illustrates a representative secondary electrochemical cell schematic having one or more TMCCC electrodes disposed in contact with a cosolvent electrolyte as described herein;

FIG. 2 illustrates a rack architecture including one string;

FIG. 3 illustrates a recovery circuit;

FIG. 4 illustrates a rack architecture including a split string arrangement; and

FIG. 5 illustrates a communication architecture for a rack including two strings in parallel using an interface unit.

### DETAILED DESCRIPTION OF THE INVENTION

Embodiments of the present invention provide a system and method optimizing electrochemical cell manufacturing by reducing commercialization costs, including reduction of electrolyte costs used in their manufacturing. The following description is presented to enable one of ordinary skill in the art to make and use the invention and is provided in the context of a patent application and its requirements.

Various modifications to the preferred embodiment and the generic principles and features described herein will be readily apparent to those skilled in the art. Thus, the present invention is not intended to be limited to the embodiment shown but is to be accorded the widest scope consistent with the principles and features described herein.

### Definitions

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The following definitions apply to some of the aspects described with respect to certain embodiments of the invention. These definitions may likewise be expanded upon herein.

As used herein, the term “or” includes “and/or” and the term “and/or” includes any and all combinations of one or more of the associated listed items. Expressions such as “at least one of,” when preceding a list of elements, modify the entire list of elements and do not modify the individual elements of the list.

As used herein, the singular terms “a,” “an,” and “the” include plural referents unless the context clearly dictates otherwise. Thus, for example, reference to an object can include multiple objects unless the context clearly dictates otherwise.

Also, as used in the description herein and throughout the claims that follow, the meaning of “in” includes “in” and “on” unless the context clearly dictates otherwise. It will be understood that when an element is referred to as being “on” another element, it can be directly on the other element or intervening elements may be present therebetween. In contrast, when an element is referred to as being “directly on” another element, there are no intervening elements present.

As used herein, the term “set” refers to a collection of one or more objects. Thus, for example, a set of objects can include a single object or multiple objects. Objects of a set also can be referred to as members of the set. Objects of a set can be the same or different. In some instances, objects of a set can share one or more common properties.

As used herein, the term “adjacent” refers to being near or adjoining. Adjacent objects can be spaced apart from one another or can be in actual or direct contact with one another. In some instances, adjacent objects can be coupled to one another or can be formed integrally with one another.

As used herein, the terms “connect,” “connected,” and “connecting” refer to a direct attachment or link. Connected objects have no or no substantial intermediary object or set of objects, as the context indicates.

As used herein, the terms “couple,” “coupled,” and “coupling” refer to an operational connection or linking. Coupled objects can be directly connected to one another or can be indirectly connected to one another, such as via an intermediary set of objects.

The use of the term “about” applies to all numeric values, whether or not explicitly indicated. This term generally refers to a range of numbers that one of ordinary skill in the art would consider as a reasonable amount of deviation to the recited numeric values (i.e., having the equivalent function or result). For example, this term can be construed as including a deviation of ±10 percent of the given numeric value provided such a deviation does not alter the end function or result of the value. Therefore, a value of about 1% can be construed to be a range from 0.9% to 1.1%.

As used herein, the terms “substantially” and “substantial” refer to a considerable degree or extent. When used in conjunction with an event or circumstance, the terms can refer to instances in which the event or circumstance occurs precisely as well as instances in which the event or circumstance occurs to a close approximation, such as accounting for typical tolerance levels or variability of the embodiments described herein.

As used herein, the terms “optional” and “optionally” mean that the subsequently described event or circumstance may or may not occur and that the description includes instances where the event or circumstance occurs and instances in which it does not.

Described herein is a new class of power bridging rack architecture for use with power storage packs that include a set of electrochemical cells having electrodes that contain transition metal cyanide coordination compound (TMCCC) materials as electrochemically active materials.

An embodiment of the present invention for a rack architecture may include one or more of the following: (a) a rack architecture divided into a power path and a low voltage path. Elements disposed in the power path are sometimes referred to as protection elements and provide protection function; (b) rack architecture low voltage path is divided into a control section and an interface section wherein the control section provides a balance function and the interface section interfaces to devices.

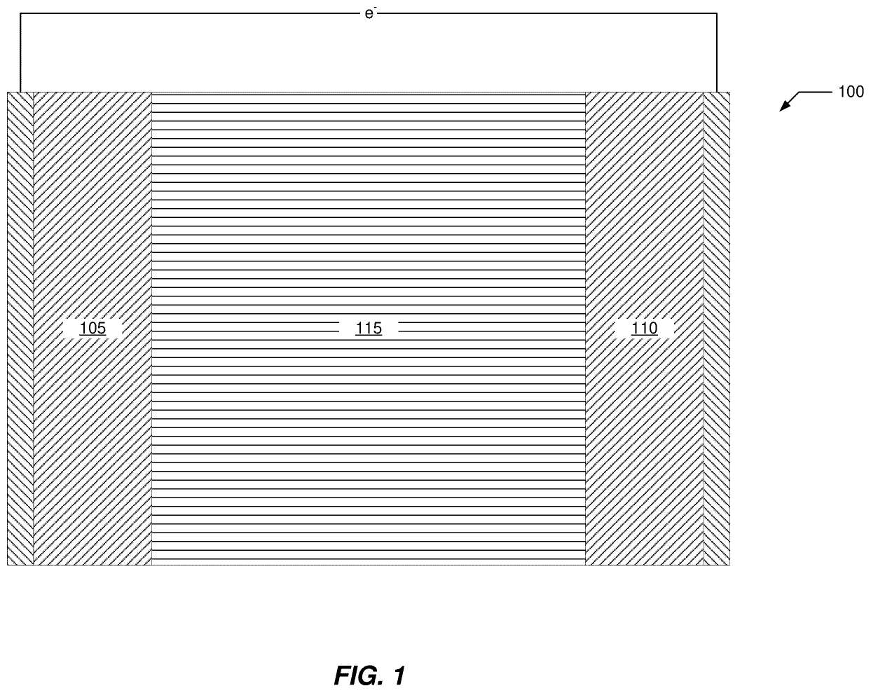

FIG. 1 illustrates a representative secondary electrochemical cell 100 schematic having one or more TMCCC electrodes disposed in contact with a cosolvent electrolyte as described herein. Cell 100 includes a negative electrode 105, a positive electrode 110 and an electrolyte 115 electrically communicated to the electrodes. Electrochemical cells including a TMCCC electrode may be configured into high power packs and further assembled into strings of packs for high power delivery and having the improved power storage characteristics enabled by these electrochemical cells.

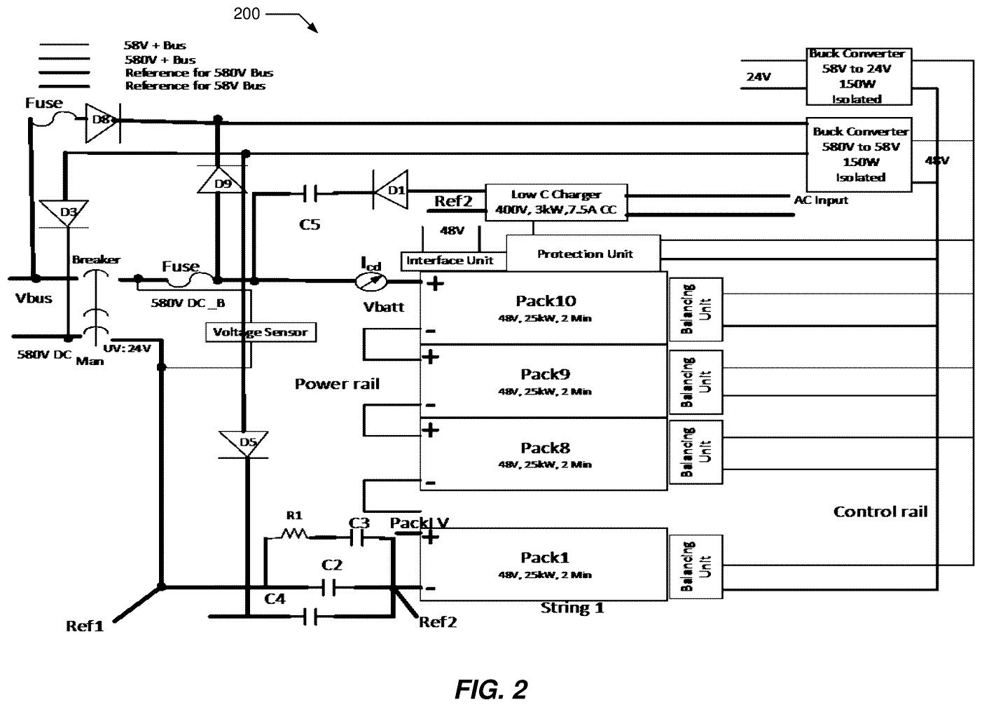

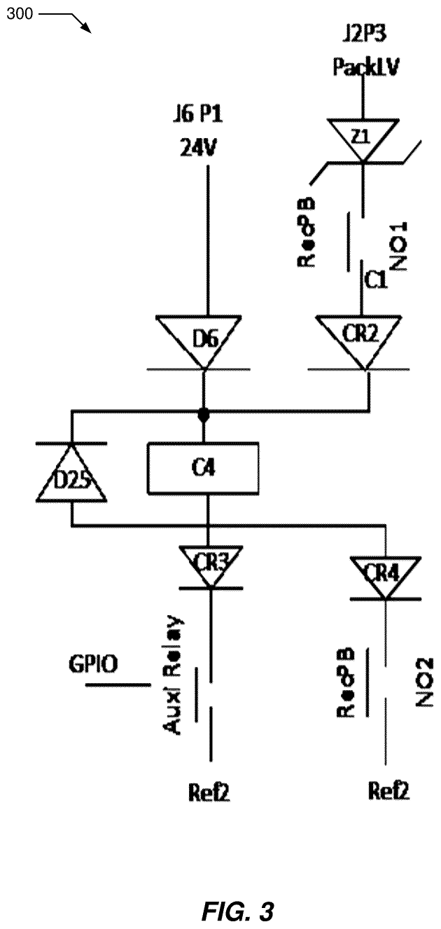

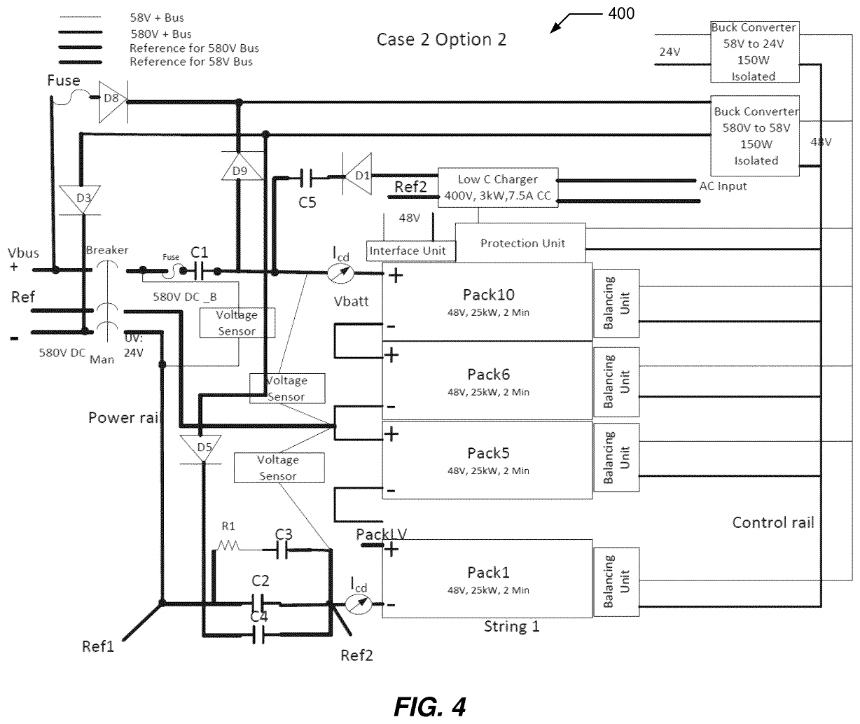

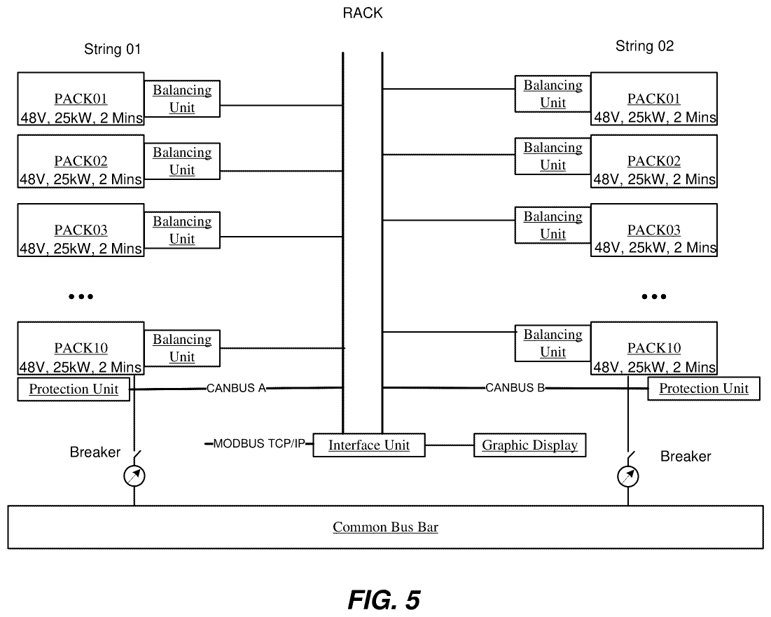

FIG. 2 illustrates a rack architecture one string; FIG. 3 illustrates a recovery circuit; FIG. 4 illustrates a rack architecture using a split string architecture; and FIG. 5 illustrates a communication architecture for a rack having two strings in parallel using an interface unit.

As illustrated in FIG. 2-FIG. 5, a rack architecture may include one or more strings of power storage devices, a split string arrangement, and an architecture including strings connected in parallel using an interface unit, each string may include one or more power storage packs connected in series. Each string may also include a protection board with protection elements. Such protection elements may include a set of contactors, fuse(s), temperature sensor(s), current sensor(s) and/or voltage sensor(s0).

FIG. 2 and FIG. 4 illustrates ten power storage packs, each pack including a balancing unit powered by buck converters providing 58V (powered from 580V-150W isolated) and 24V (powered from 58V-150W isolated) using a control rail to each associated balancing unit. An input to the string of ten packs is provided from a low C Precharge (400V, 3 KW, 7.5 A CC) from AC input. Each pack is characterized as 48V, 25 kW, and 2 Min. FIG. 2 illustrates a two-wire power transmission system while FIG. 4 illustrates a three-wire power transmission system with a split string arrangement, and further includes voltage sensing and current sensing for both +Ve and −Ve legs. Split string terminology continues to change and is sometimes alternatively referred to as split bus or split rail. In FIG. 4, mid power packs 5 and 6 include a neutral wire pulled out and broken through the breaker. These modifications are included in the power rail and therefore have no impact on the control rail.

FIG. 5 illustrates a communication architecture, two strings of ten power storage packs each. A bus bar is communicated to pack 10 of each string through a breaker. An interface unit communicates to each string through CAN buses (CANBus A to string 1 and CANBus B to string 2). Each string includes a protection unit also communicated on its associated CAN bus. The interface unit is illustrated as communicating via a graphic display and implements a MODBUS TCP/IP.

The protection board implementing the protection elements may control flow of current into the power storage packs. The protection board in sync with the balance board may control the flow of current into the power storage packs. The protection board monitors the temperature and may control the flow of current into the power storage packs. The protection board may control the amount of current into the power storage packs by monitoring a voltage status of the power storage packs.

The protection board communicates with the power storage packs through a controller area network (CAN) bus that provides a physical and data link layer (OSI). An amount of current to flow through the power storage packs determines when a pre-charge (low C charger) circuit is to be turned ON or whether/when to turn ON contactors C1 and/or C2 to charge the associate power storage pack with high current through a 580V DC bus.

The rack architecture may include two sections: (a) a first section including a high voltage section and (b) a second section including a low voltage section. The high voltage section is powered through a power rail and the low voltage section is powered through a control rail. The control rail is generated by an isolated buck converter which derives power from the power rail, powered in this example by the 580V DC bus.

An embodiment of the rack architecture may include two (or more) power storage strings, each with a dedicated protection unit, packs, and protection elements.

Short circuit protection of a rack implementing an embodiment of the disclosed architecture may be accomplished as follows: (i) when a short circuit happens, the fuse opens first; (ii) when there is an issue with the fuse opening, then the breaker opens second; and (iii) a firmware control of the contactors happens third to open the contactors in any event where the fuse or the breaker do not isolate the circuit.

Each individual power storage pack may also include a set of fuses. In an event when everything fails, then these fuses of a power storage pack will open to prevent damage to the electrochemical cells of the power storage pack.

An embodiment of the present invention for the rack architecture may also include recovery faults hardware. When a state machine (as further described herein) enters a fault state, Contactor C4 is closed and Contactor C2 is opened. This helps to maintain power to the control circuitry while disconnecting a power path. To reduce power drain on the electrochemical cells, the state machine may turn itself off by opening C4.

A recovery push button may be added to turn ON the system without external power. This circuitry routes power from one of the power storage packs to turn the circuitry.

An embodiment of the present invention may include one or more state machines, such as a protection board state machine, a balance board state machine, and an interface board state machine.

The protection board state machine may sometimes be referred to as a main controller state machine. The main controller state machine kick starts the whole rack system. This main controller state machine determines a state of the rack by monitoring the power storage packs in the strings of the system. The main controller state machine decides, based on the information provided by the power storage packs, for example monitoring a string voltage whether the system enters one of a charge mode, a precharge mode, or a discharge mode.

The balance board state machine may sometimes be referred to as a follower state machine. Each follower state machine follows the main controller state machine. A balancing state in any follower state machine is one that deviates from the state of the main controller state machine.

The interface board state machine may sometimes be referred to as a snooping state machine. The snooping state machine monitors the data traffic on the CAN bus and the captures the data for further processing.

While there may be different implementations of these state machines, examples of an implementation of these state machines may be found in patent application No. 63/468,243 filed 22 May 2023 as well as a patent application filed concurrently with this application and having application Ser. No. 18/671,438 filed 22 May 2024), these applications are hereby expressly incorporated by reference in their entireties for all purposes.)

The system and methods above have been described in general terms as an aid to understanding details of preferred embodiments of the present invention. In the description herein, numerous specific details are provided, such as examples of components and/or methods, to provide a thorough understanding of embodiments of the present invention. Some features and benefits of the present invention are realized in such modes and are not required in every case. One skilled in the relevant art will recognize, however, that an embodiment of the invention can be practiced without one or more of the specific details, or with other apparatus, systems, assemblies, methods, components, materials, parts, and/or the like. In other instances, well-known structures, materials, or operations are not specifically shown or described in detail to avoid obscuring aspects of embodiments of the present invention.

Reference throughout this specification to “one embodiment”, “an embodiment”, or “a specific embodiment” means that a particular feature, structure, or characteristic described in connection with the embodiment is included in at least one embodiment of the present invention and not necessarily in all embodiments. Thus, respective appearances of the phrases “in one embodiment”, “in an embodiment”, or “in a specific embodiment” in various places throughout this specification are not necessarily referring to the same embodiment. Furthermore, the particular features, structures, or characteristics of any specific embodiment of the present invention may be combined in any suitable manner with one or more other embodiments. It is to be understood that other variations and modifications of the embodiments of the present invention described and illustrated herein are possible in light of the teachings herein and are to be considered as part of the spirit and scope of the present invention.

It will also be appreciated that one or more of the elements depicted in the drawings/figures can also be implemented in a more separated or integrated manner, or even removed or rendered as inoperable in certain cases, as is useful in accordance with a particular application.

Additionally, any signal arrows in the drawings/Figures should be considered only as exemplary, and not limiting, unless otherwise specifically noted. Combinations of components or steps will also be considered as being noted, where terminology is foreseen as rendering the ability to separate or combine is unclear.

The foregoing description of illustrated embodiments of the present invention, including what is described in the Abstract, is not intended to be exhaustive or to limit the invention to the precise forms disclosed herein. While specific embodiments of, and examples for, the invention are described herein for illustrative purposes only, various equivalent modifications are possible within the spirit and scope of the present invention, as those skilled in the relevant art will recognize and appreciate. As indicated, these modifications may be made to the present invention in light of the foregoing description of illustrated embodiments of the present invention and are to be included within the spirit and scope of the present invention.

Thus, while the present invention has been described herein with reference to particular embodiments thereof, a latitude of modification, various changes and substitutions are intended in the foregoing disclosures, and it will be appreciated that in some instances some features of embodiments of the invention will be employed without a corresponding use of other features without departing from the scope and spirit of the invention as set forth. Therefore, many modifications may be made to adapt a particular situation or material to the essential scope and spirit of the present invention. It is intended that the invention is not limited to the particular terms used in following claims and/or to the particular embodiment disclosed as the best mode contemplated for carrying out this invention, but that the invention will include any and all embodiments and equivalents falling within the scope of the appended claims. Thus, the scope of the invention is to be determined solely by the appended claims.

What is claimed as new and desired to be protected by Letters Patent of the United States is:

1. A rack architecture for a power bridging system, comprising:
a power path; and
a low voltage path;
wherein a set of elements disposed in the power path include a set of protection elements and provide a protection function;
wherein said low voltage path is divided into a control section and an interface section; and
wherein said control section provides a balance function.

2. The rack architecture of claim 1 wherein said interface section interfaces to one or more power bridging solutions in parallel.

3. The rack architecture of claim 1 wherein said power path includes a power rail configured to support 1 to N, N≥8 number of series coupled power packs and wherein said low power path includes a control rail electrically isolated from said power rail.

4. The rack architecture of claim 3 wherein N=10.

5. The rack architecture of claim 3 wherein N=16.

6. The rack architecture of claim 3 wherein a power capacity of said power rail is scaled for a maximum power capacity of said N number of series coupled power packs while said control rail is not scaled as N changes.

7. The rack architecture of claim 1 wherein said power path, said low voltage path, and said set of elements are configured as a first power rack component responsive to said interface section including a first interface unit, further comprising a second power rack component disposed in parallel to said first power rack component, said second power rack component comprising:
a second power path; and
a second low voltage path;
wherein a second set of elements disposed in said second power path include a second set of protection elements and provide a second protection function;
wherein said second low voltage path is divided into a second control section and a second interface section;
wherein said second control section provides a second balance function; and
wherein said second interface section interfaces to said first interface section using said first interface unit.

8. The rack architecture of claim 1 wherein said power path includes a set of power storage packs disposed in a set of power strings and wherein said set of protection elements includes a main controller state machine configured to determine a state of an entire rack system by monitoring said power storage packs.

9. The rack architecture of claim 8 wherein main controller state machine includes one or more of a charge mode, a precharge mode, and a discharge mode.

10. The rack architecture of claim 8 wherein said main controller state machine includes a precharge state configured to recover to a power delivery mode when one or more power storage packs are close to a low power state that otherwise inhibits operating in said power delivery mode absent said precharge state.

11. The rack architecture of claim 1 wherein said power rail is configured with a split string structure.

12. The rack architecture of claim 11 wherein said split string structure is independent from said control rail.
